(19) United States
(12) Patent Application Publication
(10) Pub. No.: US 2015/0349267 A1
(43) Pub. Date: Dec. 3, 2015

(54) BLUE LUMINESCENT COMPOUNDS

(71) Applicant: E I DU PONT DE NEMOURS AND COMPANY, Wilmington, DE (US)

(72) Inventors: Giang Dong Vo, Wilmington, DE (US); Troy C. Gehret, Wilmington, DE (US); Ying Wang, West Chester, PA (US)

(73) Assignee: E I DU PONT DE NEMOURS AND COMPANY, Wilmington, DE (US)

(21) Appl. No.: 14/291,157

(22) Filed: May 30, 2014

(51) Int. Cl. H01L 51/00

(52) U.S. Cl. CPC H01L 51/0067; H01L 51/0085; H01L 51/5016

(57) ABSTRACT

There is provided a compound having Formula II

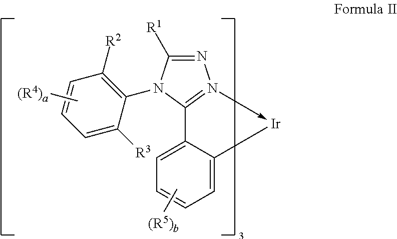

In Formula II: R¹ can be branched alkyl, cyclic alkyl, silyl, deuterated branched alkyl, deuterated cyclic alkyl, or deuterated silyl; R² and R³ are the same or different and can be alkyl, silyl, deuterated alkyl, or deuterated silyl; R⁴ and R⁵ are the same or different at each occurrence and can be D, alkyl, silyl, aryl, deuterated alkyl, deuterated silyl, and deuterated aryl; a is an integer from 0-3; and b is an integer from 0-4.

### BACKGROUND INFORMATION

1. Field of the Disclosure

This disclosure relates in general to blue luminescent compounds and their use in electronic devices.

2. Description of the Related Art

Organic electronic devices that emit light, such as light-emitting diodes that make up displays, are present in many different kinds of electronic equipment. In all such devices, an organic active layer is sandwiched between two electrical contact layers. At least one of the electrical contact layers is light-transmitting so that light can pass through the electrical contact layer. The organic active layer emits light through the light-transmitting electrical contact layer upon application of electricity across the electrical contact layers.

It is well known to use organic electroluminescent compounds as the active component in light-emitting diodes. Simple organic molecules, such as anthracene, thiadiazole derivatives, and coumarin derivatives are known to show electroluminescence. Metal complexes, particularly iridium and platinum complexes are also known to show electroluminescence. In some cases these small molecule compounds are present as a dopant in a host material to improve processing and/or electronic properties.

There is a continuing need for new luminescent compounds.

### SUMMARY

There is provided a compound having Formula I

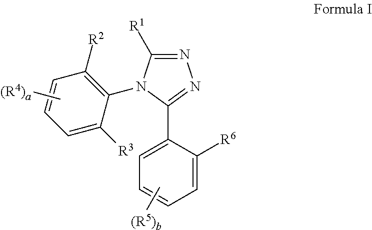

wherein:
R¹ is selected from the group consisting of branched alkyl, cyclic alkyl, silyl, and deuterated analogs thereof;
R²-R³ are the same or different and are selected from the group consisting of alkyl, silyl, and deuterated analogs thereof;
R⁴-R⁵ are the same or different at each occurrence and are selected from the group consisting of D, alkyl, silyl, aryl, deuterated alkyl, deuterated silyl, and deuterated aryl;
R⁶ is H or D;
a is an integer from 0-3; and
b is an integer from 0-4.

There is also provided a material having Formula II

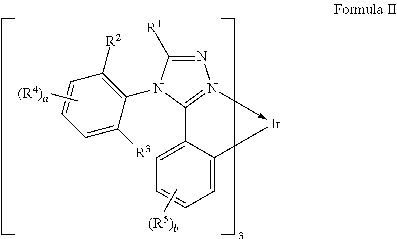

wherein:
R¹ is selected from the group consisting of branched alkyl, cyclic alkyl, silyl, and deuterated analogs thereof;
R²-R³ are the same or different and are selected from the group consisting of alkyl, silyl, and deuterated analogs thereof;
R⁴-R⁵ are the same or different at each occurrence and are selected from the group consisting of D, alkyl, silyl, aryl, deuterated alkyl, deuterated silyl, and deuterated aryl;
a is an integer from 0-3; and
b is an integer from 0-4.

There is also provided an organic electronic device comprising a first electrical contact, a second electrical contact and a photoactive layer there between, the photoactive layer comprising the material having Formula II.

The foregoing general description and the following detailed description are exemplary and explanatory only and are not restrictive of the invention, as defined in the appended claims.

### BRIEF DESCRIPTION OF THE DRAWINGS

Embodiments are illustrated in the accompanying figures to improve understanding of concepts as presented herein.

FIG. 1 includes an illustration of an organic light-emitting device.

FIG. 2 includes another illustration of an organic light-emitting device.

Skilled artisans appreciate that objects in the figures are illustrated for simplicity and clarity and have not necessarily been drawn to scale. For example, the dimensions of some of the objects in the figures may be exaggerated relative to other objects to help to improve understanding of embodiments.

### DETAILED DESCRIPTION

Many aspects and embodiments have been described above and are merely exemplary and not limiting. After reading this specification, skilled artisans appreciate that other aspects and embodiments are possible without departing from the scope of the invention.

Other features and benefits of any one or more of the embodiments will be apparent from the following detailed description, and from the claims. The detailed description first addresses Definitions and Clarification of Terms followed by the Material Having Formula I or Formula II, Synthesis, Devices, and finally Examples.

### 1. DEFINITIONS AND CLARIFICATION OF TERMS

Before addressing details of embodiments described below, some terms are defined or clarified.

The term “alkyl” is intended to mean a group derived from an aliphatic hydrocarbon and includes a linear, a branched, or a cyclic group. In some embodiments, an alkyl has from 1-20 carbon atoms.

The term “anti-quenching” when referring to a layer or material, refers to such layer or material which prevents quenching of blue luminance by the electron transport layer, either via an energy transfer or an electron transfer process.

The term “aromatic compound” is intended to mean an organic compound comprising at least one unsaturated cyclic group having delocalized pi electrons. The aromatic ring has 4n+2 pi electrons and is essentially planar.

The term “aryl” is intended to mean a group derived from an aromatic hydrocarbon having one point of attachment. The term includes groups which have a single ring and those which have multiple rings which can be joined by a single bond or fused together. The term is intended to include both hydrocarbon aryls, having only carbon in the ring structure, and heteroaryls. The term “alkylaryl” is intended to mean an aryl group having one or more alkyl substituents. In some embodiments, a hydrocarbon aryl has 6-60 ring carbons. In some embodiments, a heteroaryl has 3-60 ring carbons.

The term “branched alkyl” is intended to mean a group derived from an aliphatic hydrocarbon that has at least one secondary or tertiary carbon. A secondary alkyl group has the structure:

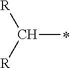

where the R groups are the same or different and are alkyl groups and the asterisk represents the point of attachment to the triazole ring. An exemplary secondary alkyl group is an isopropyl group. A tertiary alkyl group has the structure:

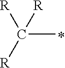

where the R groups are the same or different and are alkyl groups and the asterisk represents the point of attachment to the triazole ring. An exemplary tertiary alkyl group is a t-butyl group.

The term “charge transport,” when referring to a layer, material, member, or structure is intended to mean such layer, material, member, or structure facilitates migration of such charge through the thickness of such layer, material, member, or structure with relative efficiency and small loss of charge. Hole transport materials facilitate positive charge; electron transport materials facilitate negative charge. Although light-emitting materials may also have some charge transport properties, the term “charge transport layer, material, member, or structure” is not intended to include a layer, material, member, or structure whose primary function is light emission.

The term “cyclic alkyl” is intended to mean a group derived from an aliphatic hydrocarbon that has 4-20 carbon atoms in an aliphatic ring. The ring may have on or more double bonds but is not aromatic. A cyclic alkyl may be monocyclic or polycyclic.

The term “deuterated” is intended to mean that at least one hydrogen has been replaced by deuterium, abbreviated herein as “D”. The term “deuterated analog” refers to a structural analog of a compound or group in which one or more available hydrogens have been replaced with deuterium. In a deuterated compound or deuterated analog, the deuterium is present in at least 100 times the natural abundance level.

The term “dopant” is intended to mean a material, within a layer including a host material, that changes the electronic characteristic(s) or the targeted wavelength(s) of radiation emission, reception, or filtering of the layer compared to the electronic characteristic(s) or the wavelength(s) of radiation emission, reception, or filtering of the layer in the absence of such material.

The prefix “hetero” indicates that one or more carbon atoms have been replaced with a different atom. In some embodiments, the different atom is N, O, or S.

The term “host material” is intended to mean a material, usually in the form of a layer, to which a dopant may be added. The host material may or may not have electronic characteristic(s) or the ability to emit, receive, or filter radiation.

The terms “luminescent material” and “emitter” are intended to mean a material that emits light when activated by an applied voltage (such as in a light-emitting diode or light-emitting electrochemical cell). The term “layer” is used interchangeably with the term “film” and refers to a coating covering a desired area. The term is not limited by size. The area can be as large as an entire device or as small as a specific functional area such as the actual visual display, or as small as a single sub-pixel. Layers and films can be formed by any conventional deposition technique, including vapor deposition, liquid deposition (continuous and discontinuous techniques), and thermal transfer. Continuous deposition techniques, include but are not limited to, spin coating, gravure coating, curtain coating, dip coating, slot-die coating, spray coating, and continuous nozzle coating or printing. Discontinuous deposition techniques include, but are not limited to, ink jet printing, gravure printing, and screen printing.

The term “organic electronic device” or sometimes just “electronic device” is intended to mean a device including one or more organic semiconductor layers or materials.

The term “photoactive” refers to a material or layer that emits light when activated by an applied voltage (such as in a light emitting diode or chemical cell) or responds to radiant energy and generates a signal with or without an applied bias voltage (such as in a photodetector or a photovoltaic cell).

All groups may be unsubstituted or substituted. The substituent groups are discussed below.

In this specification, unless explicitly stated otherwise or indicated to the contrary by the context of usage, where an embodiment of the subject matter hereof is stated or described as comprising, including, containing, having, being composed of or being constituted by or of certain features or elements, one or more features or elements in addition to those explicitly stated or described may be present in the embodiment. An alternative embodiment of the disclosed subject matter hereof, is described as consisting essentially of certain features or elements, in which embodiment features or elements that would materially alter the principle of operation or the distinguishing characteristics of the embodiment are not present therein. A further alternative embodiment of the described subject matter hereof is described as consisting of certain features or elements, in which embodiment, or in insubstantial variations thereof, only the features or elements specifically stated or described are present.

Also, use of “a” or “an” are employed to describe elements and components described herein. This is done merely for convenience and to give a general sense of the scope of the invention. This description should be read to include one or at least one and the singular also includes the plural unless it is obvious that it is meant otherwise.

Group numbers corresponding to columns within the Periodic Table of the elements use the “New Notation” convention as seen in the CRC Handbook of Chemistry and Physics, 81^{st} Edition (2000-2001).

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. In case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, photodetector, photovoltaic cell, and semiconductive member arts.

### 2. COMPOUNDS HAVING FORMULA I OR FORMULA II

There is provided herein a new compound having Formula I

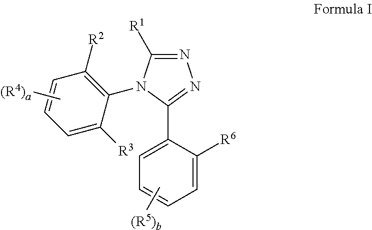

wherein:
R¹ is selected from the group consisting of branched alkyl, cyclic alkyl, silyl, and deuterated analogs thereof;
R²-R³ are the same or different and are selected from the group consisting of alkyl, silyl, and deuterated analogs thereof;
R⁴-R⁵ are the same or different at each occurrence and are selected from the group consisting of D, alkyl, silyl, aryl, deuterated alkyl, deuterated silyl, and deuterated aryl;
R⁶ is H or D;
a is an integer from 0-3; and
b is an integer from 0-4.

The new compounds having Formula I can be used as ligands to form transition metal complexes.

In some embodiments, the transition metal complexes include the compounds of Formula I coordinated to metals selected from the group including Pt, Os, Ru, Rh, and Ir.

The new compounds having Formula I can be used as ligands to form metal complexes having Formula II

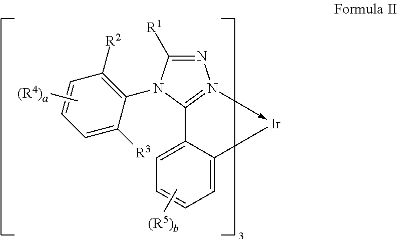

wherein:
R¹ is selected from the group consisting of branched alkyl, cyclic alkyl, silyl, and deuterated analogs thereof;
R²-R³ are the same or different and are selected from the group consisting of alkyl, silyl, and deuterated analogs thereof;
R⁴-R⁵ are the same or different at each occurrence and are selected from the group consisting of D, alkyl, silyl, aryl, deuterated alkyl, deuterated silyl, and deuterated aryl;
a is an integer from 0-3; and
b is an integer from 0-4.

In some embodiments, the compounds having Formula II are useful as emissive materials. The compound having Formula II are capable of blue electroluminescence. The compounds can be used alone or as a dopant in a host material.

The compounds having Formula II are soluble in many commonly used organic solvents. Solutions of these compounds can be used for liquid deposition using techniques such as discussed above. Surprisingly, it has been found that compounds having both an alkyl group which is branched at the point of attachment to the triazole ring in the R¹ position below and substituents at R² and R³ have an unexpected shift in emission towards blue

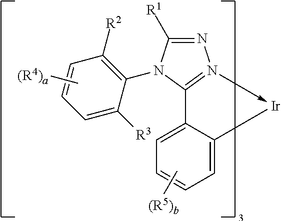

The shift toward blue can be seen as a decrease in the wavelength of the peak of maximum emission. The shift toward blue can be seen as a decrease in the color coordinates of emission, according to the chromaticity scale.

In some embodiments, the compounds have an electroluminescent (“EL”) peak less than 500 nm. In some embodiments, the compounds have an EL peak in the range of 445-490 nm. In some embodiments, the compounds have an EL peak in the range 460-480 nm. In some embodiments, the compounds used in devices result in color coordinates of x<0.25 and y<0.5, according to the 1931 C.I.E. convention (Commission Internationale de L'Eclairage, 1931). In some embodiments, the color coordinates are x<0.20 and y<0.4; in some embodiments, x <0.18 and y<0.35.

Also surprisingly, such compounds provide other advantages in electronic devices. In some embodiments, devices made with compounds having Formula II have improved efficiencies and lifetimes. This is advantageous for reducing energy consumption in all types of devices, and particularly for lighting applications. Higher efficiency also improves device lifetime at constant luminance.

Specific embodiments of the present invention include, but are not limited to, the following.

In some embodiments, the compound of Formula I or Formula II is deuterated.

In some embodiments, the compound of Formula I or Formula II is at least 10% deuterated. By “% deuterated” or “% deuteration” is meant the ratio of deuterons to the total of hydrogens plus deuterons, expressed as a percentage. The deuteriums may be on the same or different groups.

In some embodiments, the compound of Formula I or Formula II is at least 25% deuterated.

In some embodiments, the compound of Formula I or Formula II is at least 50% deuterated.

In some embodiments, the compound of Formula I or Formula II is at least 75% deuterated.

In some embodiments, the compound of Formula I or Formula II is at least 90% deuterated.

In some embodiments of the compound of Formula I or Formula II, R¹ is a branched alkyl or deuterated branched alkyl having 3-20 carbons.

In some embodiments of the compound of Formula I or Formula II, R¹ is a branched alkyl or deuterated branched alkyl having 3-10 carbons, and the branch occurs at a secondary or tertiary carbon atom that is directly bound to the triazole ring. Further branching may also occur at other locations on R¹.

In some embodiments of the compound of Formula I or Formula II, R¹ is a branched alkyl or deuterated branched alkyl having 4-6 carbons.

In some embodiments of the compound of Formula I or Formula II, R¹ is a monocyclic alkyl or deuterated monocyclic alkyl having 4-20 ring carbons. Multiple cycloalkyl groups may be present.

In some embodiments of the compound of Formula I or Formula II, R¹ is a monocyclic alkyl or deuterated monocyclic alkyl having 6-12 ring carbons.

In some embodiments of the compound of Formula I or Formula II, R¹ is a monocyclic alkyl or deuterated monocyclic alkyl having 8-10 ring carbons.

In some embodiments of the compound of Formula I or Formula II, R¹ is a polycyclic alkyl or deuterated polycyclic alkyl having 6-20 ring carbons.

In some embodiments of the compound of Formula I or Formula II, R¹ is a polycyclic alkyl or deuterated polycyclic alkyl having 8-12 ring carbons.

In some embodiments of the compound of Formula I or Formula II, R¹ is a silyl or deuterated silyl having 3-6 carbons.

In some embodiments of the compound of Formula I or Formula II, R² and R³ are the same group.

In some embodiments of the compound of Formula I or Formula II, R² and R³ are different groups.

In some embodiments of the compound of Formula I or Formula II, R² and R³ are alkyl or deuterated alkyl groups having 1-6 carbons.

In some embodiments of the compound of Formula I or Formula II, R² and R³ are alkyl or branched deuterated alkyl groups having 3-6 carbons.

In some embodiments of the compound of Formula I or Formula II, R² and R³ are silyl groups having 3-6 carbons.

In some embodiments of the compound of Formula I or Formula II, a=0.

In some embodiments of the compound of Formula I or Formula II, a=1.

In some embodiments of the compound of Formula I or Formula II, a=2.

In some embodiments of the compound of Formula I or Formula II, a=3.

In some embodiments of the compound of Formula I or Formula II, a>0 and R⁴ is an alkyl or deuterated alkyl having 1-6 carbons.

In some embodiments of the compound of Formula I or Formula II, a>0 and R⁴ is silyl or deuterated silyl having 3-6 carbons. In some embodiments of the compound of Formula I or Formula II, a>0 and R⁴ is an aryl or deuterated aryl having 6-12 ring carbons.

In some embodiments of the compound of Formula I or Formula II, b=0.

In some embodiments of the compound of Formula I or Formula II, b=1.

In some embodiments of the compound of Formula I or Formula II, b=2.

In some embodiments of the compound of Formula I or Formula II, b=3.

In some embodiments of the compound of Formula I or Formula II, b=4.

In some embodiments of the compound of Formula I or Formula II, b>0 and R⁵ is an alkyl or deuterated alkyl having 1-6 carbons.

In some embodiments of the compound of Formula I or Formula II, b>0 and R⁵ is silyl or deuterated silyl having 3-6 carbons.

In some embodiments of the compound of Formula I or Formula II, b>0 and R⁵ is an aryl or deuterated aryl having 6-12 ring carbons.

Any of the above embodiments can be combined with one or more of the other embodiments, so long as they are not mutually exclusive. For example, the embodiment in which R¹ is a branched alkyl or deuterated branched alkyl having 1-20 carbons can be combined with the embodiment in which R² and R³ are branched alkyl or branched deuterated alkyl groups having 1-6 carbons. The same is true for the other non-mutually-exclusive embodiments discussed above. The skilled person would understand which embodiments were mutually exclusive and would thus readily be able to determine the combinations of embodiments that are contemplated by the present application.

Examples of compounds having Formula I include, but are not limited to, the compounds shown below.

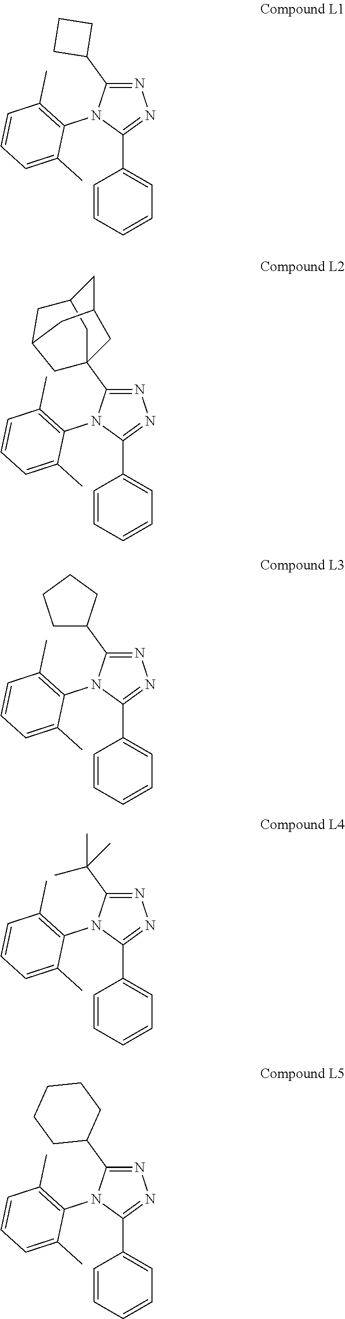

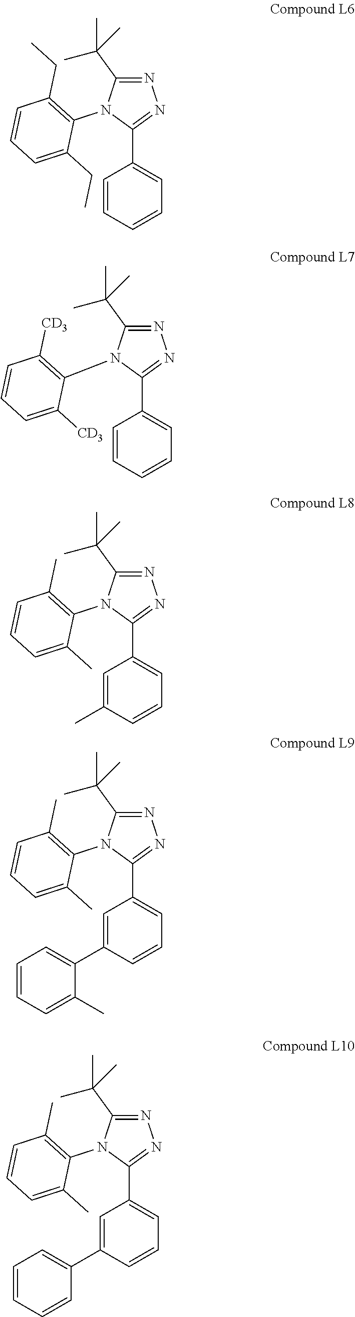

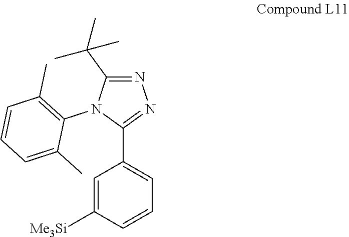 [SMILES: Cc1cccc(C)c1-n1c(-c2cccc([Si](C)(C)C)c2)nnc1C(C)(C)C]

Examples of compounds having Formula II include, but are not limited to, the compounds shown below.

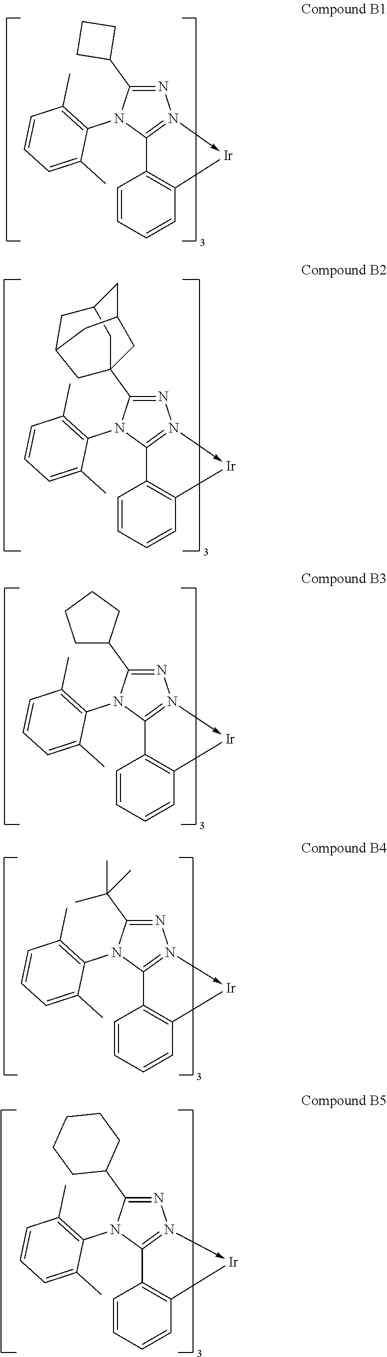

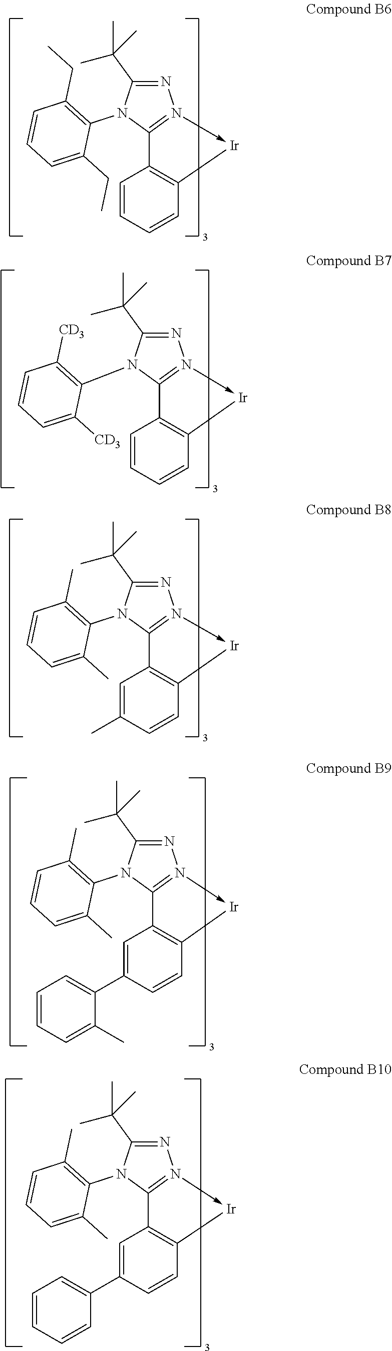

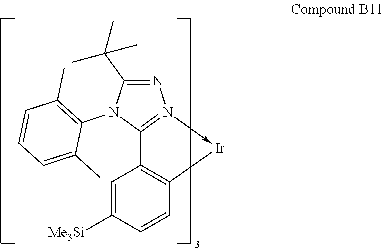

### 3. SYNTHESIS

The compounds having Formula I described herein can be synthesized by a variety of procedures that have precedent in the literature. The exact procedure chosen will depend on a variety of factors, including availability of starting materials and reaction yield.

In one procedure (shown below), an alkyl carboxylic acid is allowed to react with oxalyl chloride in the presence of catalytic amounts of N,N-dimethylformamide (DMF). The resulting acyl chloride is then treated in situ with 5-phenyl-1H-tetrazole and pyridine at 100° C. to give a 2-(alkyl)-5-phenyl-1,3,4-oxadiazole, which is isolated. In the final step, an aniline is allowed to react with AlCl₃ and then treated with the 2-(alkyl)-5-phenyl-1,3,4-oxadiazole followed by 1-methyl-2-pyrrolidinone (NMP). The mixture is heated to reflux (internal temperature ˜215° C.) to form an 3-(alkyl)-4,5-diphenyl-4H-1,2,4-triazole (Formula 1), which is isolated and purified.

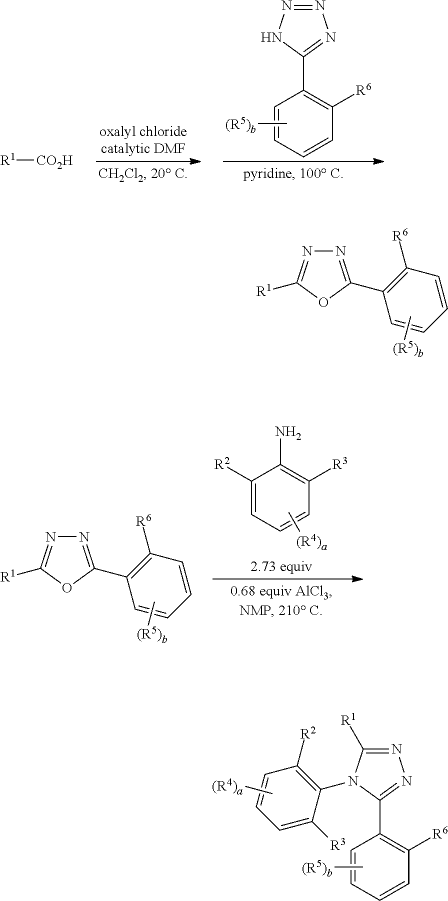

The compounds having Formula II can be prepared by the reaction of commercially available Ir(acetylacetonate)₃ with excess ligand at elevated temperatures. This reaction typically results in cyclometallation of three equivalents of ligand onto iridium and formation of three equivalents of acetylacetone. The IrL₃ product, wherein L is the cyclometallated ligand, can be isolated and purified by chromatography and/or recrystallization.

### 4. DEVICES

Organic electronic devices that may benefit from having one or more layers comprising the compounds having Formula II described herein include, but are not limited to: (1) devices that convert electrical energy into radiation (e.g., a light-emitting diode, light emitting diode display, diode laser, or lighting panel), (2) devices that detect a signal using an electronic process (e.g., a photodetector, a photoconductive cell, a photoresistor, a photoswitch, a phototransistor, a phototube, an infrared (“IR”) detector, or a biosensors), (3) devices that convert radiation into electrical energy (e.g., a photovoltaic device or solar cell), (4) devices that convert light of one wavelength to light of a longer wavelength, (e.g., a down-converting phosphor device); (5) devices that include one or more electronic components that include one or more organic semiconductor layers (e.g., a transistor or diode), or any combination of devices in items (1) through (5).

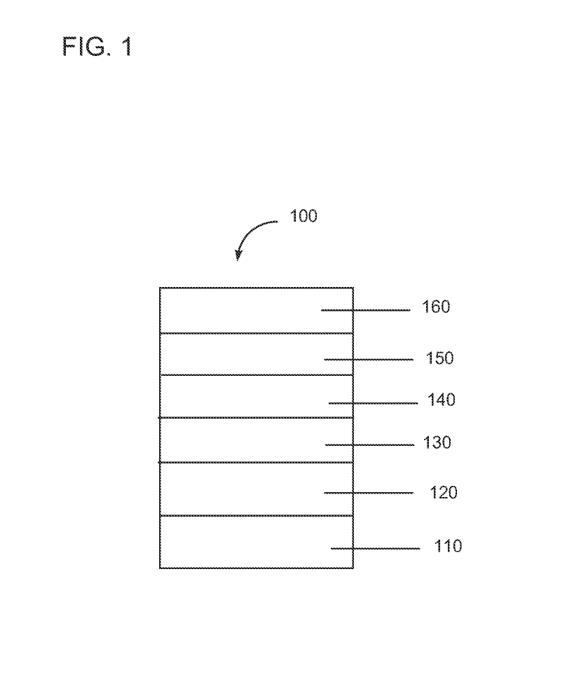

One illustration of an organic electronic device structure is shown in FIG. 1. The device 100 has a first electrical contact layer, an anode layer 110 and a second electrical contact layer, a cathode layer 160, and a photoactive layer 140 between them. Adjacent to the anode is a hole injection layer 120. Adjacent to the hole injection layer is a hole transport layer 130, comprising hole transport material. Adjacent to the cathode may be an electron transport layer 150, comprising an electron transport material. As an option, devices may use one or more additional hole injection or hole transport layers (not shown) next to the anode 110 and/or one or more additional electron injection or electron transport layers (not shown) next to the cathode 160. As a further option, devices may have an anti-quenching layer (not shown) between the photoactive layer 140 and the electron transport layer 150.

Layers 120 through 150, and any additional layers between them, are individually and collectively referred to as the active layers.

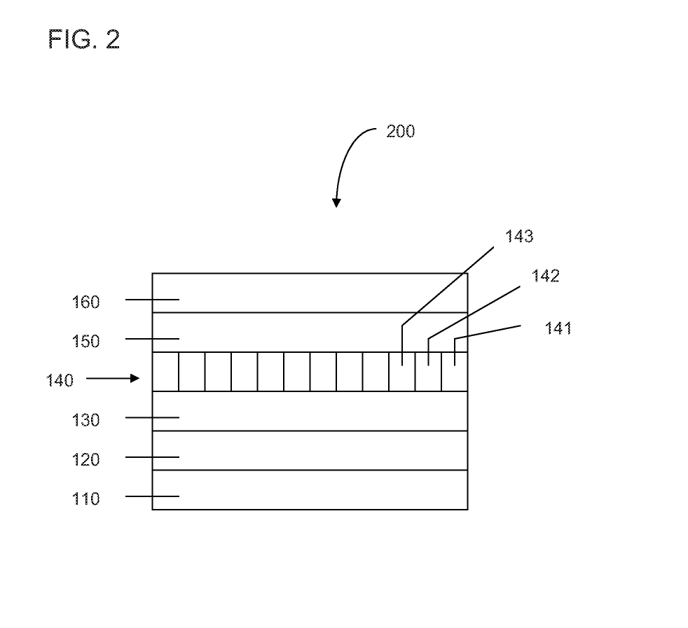

In some embodiments, the photoactive layer is pixellated, as shown in FIG. 2. In device 200, layer 140 is divided into pixel or subpixel units 141, 142, and 143 which are repeated over the layer. Each of the pixel or subpixel units represents a different color. In some embodiments, the subpixel units are for red, green, and blue. Although three subpixel units are shown in the figure, two or more than three may be used.

In some embodiments, the different layers have the following range of thicknesses: anode 110, 500-5000 Å, in some embodiments, 1000-2000 Å; hole injection layer 120, 50-2000 Å, in some embodiments, 200-1000 Å; hole transport layer 130, 50-3000 Å, in some embodiments, 200-2000 Å; photoactive layer 140, 10-2000 Å, in some embodiments, 100-1000 Å; electron transport layer 150, 50-2000 Å, in some embodiments, 100-1000 Å; cathode 160, 200-10000 Å, in some embodiments, 300-5000 Å. The desired ratio of layer thicknesses will depend on the exact nature of the materials used. The location of the electron-hole recombination zone in the device, and thus the emission spectrum of the device, can be affected by the relative thickness of each layer. The desired ratio of layer thicknesses will depend on the exact nature of the materials used.

In some embodiments, the compounds having Formula II are useful as the emissive material in photoactive layer 140, having blue emission color. They can be used alone or as a dopant in a host material.

a. Photoactive Layer

In some embodiments, the photoactive layer comprises a host material and a compound having Formula II as a dopant. In some embodiments, a second host material may be present. In some embodiments, the photoactive layer consists essentially of a host material and a compound having Formula II as a dopant. In some embodiments, the photoactive layer consists essentially of a first host material, a second host material, and a compound having Formula II as a dopant. The weight ratio of dopant to total host material is in the range of 5:95 to 70:30; in some embodiments, 10:90 to 20:80.

In some embodiments, the host has a triplet energy level higher than that of the dopant, so that it does not quench the emission. In some embodiments, the host is selected from the group consisting of carbazoles, indolocarbazoles, triazines, aryl ketones, phenylpyridines, pyrimidines, phenanthrolines, triarylamines, deuterated analogs thereof, combinations thereof, and mixtures thereof.

In some embodiments, the photoactive layer is intended to emit white light. In some embodiments, the photoactive layer comprises a host, a compound of Formula II, and one or more additional dopants emitting different colors, so that the overall emission is white. In some embodiments, the photoactive layer consists essentially of a host, a first dopant having Formula II, and a second dopant, where the second dopant emits a different color than the first dopant. In some embodiments, the emission color of the second dopant is yellow. In some embodiments, the photoactive layer consists essentially of a host, a first dopant having Formula II, a second dopant, and a third dopant. In some embodiments, the emission color of the second dopant is red and the emission color of the third dopant is green.

Any kind of electroluminescent (“EL”) material can be used as second and third dopants. EL materials include, but are not limited to, small molecule organic fluorescent compounds, luminescent metal complexes, conjugated polymers, and mixtures thereof. Examples of fluorescent compounds include, but are not limited to, chrysenes, pyrenes, perylenes, rubrenes, coumarins, anthracenes, thiadiazoles, derivatives thereof, arylamino derivatives thereof, and mixtures thereof. Examples of metal complexes include, but are not limited to, metal chelated oxinoid compounds, such as tris(8-hydroxyquinolato)aluminum (Alq3); cyclometalated iridium and platinum electroluminescent compounds, such as complexes of iridium with phenylpyridine, phenylquinoline, or phenylpyrimidine ligands as disclosed in Petrov et al., U.S. Pat. No. 6,670,645 and Published PCT Applications WO 03/063555 and WO 2004/016710, and organometallic complexes described in, for example, Published PCT Applications WO 03/008424, WO 03/091688, and WO 03/040257, and mixtures thereof. Examples of conjugated polymers include, but are not limited to poly(phenylenevinylenes), polyfluorenes, poly(spirobifluorenes), polythiophenes, poly(p-phenylenes), copolymers thereof, and mixtures thereof.

Examples of red, orange and yellow light-emitting materials include, but are not limited to, complexes of Ir having phenylquinoline or phenylisoquinoline ligands, periflanthenes, fluoranthenes, and perylenes. Red light-emitting materials have been disclosed in, for example, U.S. Pat. No. 6,875,524, and published US application 2005-0158577.

In some embodiments, the second and third dopants are cyclometallated complexes of Ir or Pt.

b. Other Device Layers

The other layers in the device can be made of any materials which are known to be useful in such layers.

The anode 110 is an electrode that is particularly efficient for injecting positive charge carriers. It can be made of, for example materials containing a metal, mixed metal, alloy, metal oxide or mixed-metal oxide, or it can be a conducting polymer, and mixtures thereof. Suitable metals include the Group 11 metals, the metals in Groups 4, 5, and 6, and the Group 8-10 transition metals. If the anode is to be light-transmitting, mixed-metal oxides of Groups 12, 13 and 14 metals, such as indium-tin-oxide, are generally used. The anode may also comprise an organic material such as polyaniline as described in “Flexible light-emitting diodes made from soluble conducting polymer,” Nature vol. 357, pp 477 479 (11 Jun. 1992). At least one of the anode and cathode should be at least partially transparent to allow the generated light to be observed.

The hole injection layer 120 comprises hole injection material and may have one or more functions in an organic electronic device, including but not limited to, planarization of the underlying layer, charge transport and/or charge injection properties, scavenging of impurities such as oxygen or metal ions, and other aspects to facilitate or to improve the performance of the organic electronic device. The hole injection layer can be formed with polymeric materials, such as polyaniline (PANI) or polyethylenedioxythiophene (PEDOT), which are often doped with protonic acids. The protonic acids can be, for example, poly(styrenesulfonic acid), poly(2-acrylamido-2-methyl-1-propanesulfonic acid), and the like.

The hole injection layer can comprise charge transfer compounds, and the like, such as copper phthalocyanine and the tetrathiafulvalene-tetracyanoquinodimethane system (TTF-TCNQ).

In some embodiments, the hole injection layer comprises at least one electrically conductive polymer and at least one fluorinated acid polymer.

In some embodiments, the hole injection layer is made from an aqueous dispersion of an electrically conducting polymer doped with a colloid-forming polymeric acid. Such materials have been described in, for example, published U.S. patent applications US 2004/0102577, US 2004/0127637, US 2005/0205860, and published PCT application WO 2009/018009.

Examples of hole transport materials for layer 130 have been summarized for example, in Kirk-Othmer Encyclopedia of Chemical Technology, Fourth Edition, Vol. 18, p. 837-860, 1996, by Y. Wang. Both hole transporting molecules and polymers can be used. Commonly used hole transporting molecules are: N,N′-diphenyl-N,N′-bis(3-methylphenyl)-[1,1′-biphenyl]-4,4′-diamine (TPD), 1,1-bis[(di-4-tolylamino) phenyl]cyclohexane (TAPC), N,N′-bis(4-methylphenyl)-N,N′-bis(4-ethylphenyl)-[1,1′-(3,3′-dimethyl)biphenyl]-4,4′-diamine (ETPD), tetrakis-(3-methylphenyl)-N,N,N′,N′-2,5-phenylenediamine (PDA), a-phenyl-4-N,N-diphenylaminostyrene (TPS), p-(diethylamino)benzaldehyde diphenylhydrazone (DEH), triphenylamine (TPA), bis[4-(N,N-diethylamino)-2-methylphenyl](4-methylphenyl)methane (MPMP), 1-phenyl-3-[p-(diethylamino)styryl]-5-[p-(diethylamino)phenyl]pyrazoline (PPR or DEASP), 1,2-trans-bis(9H-carbazol-9-yl)cyclobutane (DCZB), N,N,N′,N′-tetrakis(4-methylphenyl)-(1,1′-biphenyl)-4,4′-diamine (TTB), N,N′-bis(naphthalen-1-yl)-N,N′-bis-(phenyl)benzidine (-NPB), and porphyrinic compounds, such as copper phthalocyanine. In some embodiments, the hole transport layer comprises a hole transport polymer. In some embodiments, the hole transport polymer is a distyrylaryl compound. In some embodiments, the aryl group has two or more fused aromatic rings. In some embodiments, the aryl group is an acene. The term “acene” as used herein refers to a hydrocarbon parent component that contains two or more ortho-fused benzene rings in a straight linear arrangement. Other commonly used hole transporting polymers are polyvinylcarbazole, (phenylmethyl)-polysilane, and polyaniline. It is also possible to obtain hole transporting polymers by doping hole transporting molecules such as those mentioned above into polymers such as polystyrene and polycarbonate. In some cases, triarylamine polymers are used, especially triarylamine-fluorene copolymers. In some cases, the polymers and copolymers are crosslinkable.

In some embodiments, the hole transport layer further comprises a p-dopant. In some embodiments, the hole transport layer is doped with a p-dopant. Examples of p-dopants include, but are not limited to, tetrafluorotetracyanoquinodimethane (F4-TCNQ) and perylene-3,4,9,10-tetracarboxylic-3,4,9,10-dianhydride (PTCDA).

Examples of electron transport materials which can be used for layer 150 include, but are not limited to, metal chelated oxinoid compounds, including metal quinolate derivatives such as tris(8-hydroxyquinolato)aluminum (AIQ), bis(2-methyl-8-quinolinolato)(p-phenylphenolato) aluminum (BAIq), tetrakis-(8-hydroxyquinolato)hafnium (HfQ) and tetrakis-(8-hydroxyquinolato)zirconium (ZrQ); and azole compounds such as 2-(4-biphenylyl)-5-(4-t-butylphenyl)-1,3,4-oxadiazole (PBD), 3-(4-biphenylyl)-4-phenyl-5-(4-t-butylphenyl)-1,2,4-triazole (TAZ), and 1,3,5-tri(phenyl-2-benzimidazole)benzene (TPBI); quinoxaline derivatives such as 2,3-bis(4-fluorophenyl)quinoxaline; phenanthrolines such as 4,7-diphenyl-1,10-phenanthroline (DPA) and 2,9-dimethyl-4,7-diphenyl-1,10-phenanthroline (DDPA); and mixtures thereof. In some embodiments, the electron transport layer further comprises an n-dopant. N-dopant materials are well known. The n-dopants include, but are not limited to, Group 1 and 2 metals; Group 1 and 2 metal salts, such as LiF, CsF, and Cs₂CO₃; Group 1 and 2 metal organic compounds, such as Li quinolate; and molecular n-dopants, such as leuco dyes, metal complexes, such as W₂(hpp)₄ where hpp=1,3,4,6,7,8-hexahydro-2H-pyrimido-[1,2-a]-pyrimidine and cobaltocene, tetrathianaphthacene, bis(ethylenedithio)tetrathiafulvalene, heterocyclic radicals or diradicals, and the dimers, oligomers, polymers, dispiro compounds and polycycles of heterocyclic radical or diradicals.

An anti-quenching layer may be present between the photoactive layer and the electron transport layer to prevent quenching of blue luminance by the electron transport layer. To prevent energy transfer quenching, the triplet energy of the anti-quenching material has to be higher than the triplet energy of the blue emitter. To prevent electron transfer quenching, the LUMO level of the anti-quenching material has to be shallow enough (with respect to the vacuum level) such that electron transfer between the emitter exciton and the anti-quenching material is endothermic. Furthermore, the HOMO level of the anti-quenching material has to be deep enough (with respect to the vacuum level) such that electron transfer between the emitter exciton and the anti-quenching material is endothermic. In general, anti-quenching material is a large band-gap material with high triplet energy.

Examples of materials for the anti-quenching layer include, but are not limited to, triphenylene, triphenylene derivatives, carbazole, carbazole derivatives, and deuterated analogs thereof. Some specific materials include those shown below.

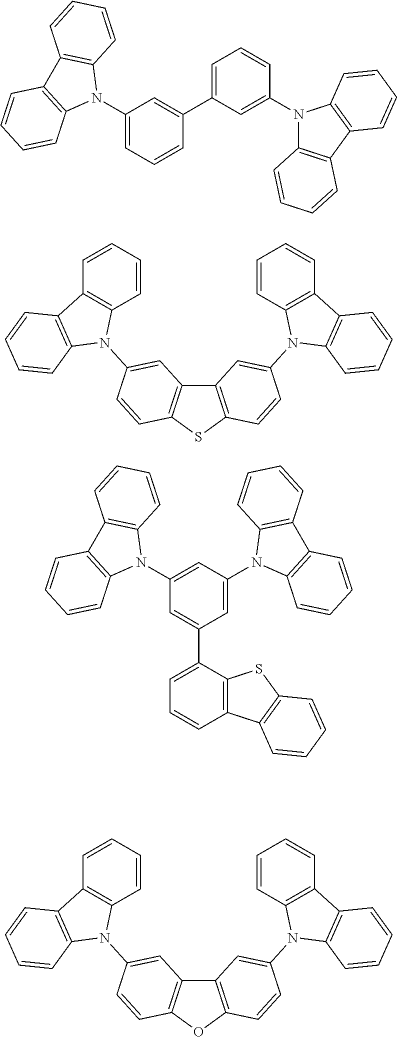

An optional electron injection layer may be deposited over the electron transport layer. Examples of electron injection materials include, but are not limited to, Li-containing organometallic compounds, LiF, Li₂O, Li quinolate, Cs-containing organometallic compounds, CsF, Cs₂O, and Cs₂CO₃. This layer may react with the underlying electron transport layer, the overlying cathode, or both. When an electron injection layer is present, the amount of material deposited is generally in the range of 1-100 Å, in some embodiments 1-10 Å.

The cathode 160, is an electrode that is particularly efficient for injecting electrons or negative charge carriers. The cathode can be any metal or nonmetal having a lower work function than the anode. Materials for the cathode can be selected from alkali metals of Group 1 (e.g., Li, Cs), the Group 2 (alkaline earth) metals, the Group 12 metals, including the rare earth elements and lanthanides, and the actinides. Materials such as aluminum, indium, calcium, barium, samarium and magnesium, as well as combinations, can be used.

It is known to have other layers in organic electronic devices. For example, there can be a layer (not shown) between the anode 110 and hole injection layer 120 to control the amount of positive charge injected and/or to provide band-gap matching of the layers, or to function as a protective layer. Layers that are known in the art can be used, such as copper phthalocyanine, silicon oxy-nitride, fluorocarbons, silanes, or an ultra-thin layer of a metal, such as Pt. Alternatively, some or all of anode layer 110, active layers 120, 130, 140, and 150, or cathode layer 160, can be surface-treated to increase charge carrier transport efficiency. The choice of materials for each of the component layers is preferably determined by balancing the positive and negative charges in the emitter layer to provide a device with high electroluminescence efficiency.

It is understood that each functional layer can be made up of more than one layer.

c. Device Fabrication

The device layers can be formed by any deposition technique, or combinations of techniques, including vapor deposition, liquid deposition, and thermal transfer.

In some embodiments, the device is fabricated by liquid deposition of the hole injection layer, the hole transport layer, and the photoactive layer, and by vapor deposition of the anode, the electron transport layer, an electron injection layer and the cathode.

The hole injection layer can be deposited from any liquid medium in which it is dissolved or dispersed and from which it will form a film. In one embodiment, the liquid medium consists essentially of one or more organic solvents. In one embodiment, the liquid medium consists essentially of water or water and an organic solvent. The hole injection material can be present in the liquid medium in an amount from 0.5 to 10 percent by weight. The hole injection layer can be applied by any continuous or discontinuous liquid deposition technique. In one embodiment, the hole injection layer is applied by spin coating. In one embodiment, the hole injection layer is applied by ink jet printing. In one embodiment, the hole injection layer is applied by continuous nozzle printing. In one embodiment, the hole injection layer is applied by slot-die coating. After liquid deposition, the liquid medium can be removed in air, in an inert atmosphere, or by vacuum, at room temperature or with heating.

The hole transport layer can be deposited from any liquid medium in which it is dissolved or dispersed and from which it will form a film. In one embodiment, the liquid medium consists essentially of one or more organic solvents. In one embodiment, the liquid medium consists essentially of water or water and an organic solvent. In one embodiment the organic solvent is an aromatic solvent. In one embodiment, the organic liquid is selected from chloroform, dichloromethane, chlorobenzene, dichlorobenzene, toluene, xylene, mesitylene, anisole, and mixtures thereof. The hole transport material can be present in the liquid medium in a concentration of 0.2 to 2 percent by weight. The hole transport layer can be applied by any continuous or discontinuous liquid deposition technique. In one embodiment, the hole transport layer is applied by spin coating. In one embodiment, the hole transport layer is applied by ink jet printing. In one embodiment, the hole transport layer is applied by continuous nozzle printing. In one embodiment, the hole transport layer is applied by slot-die coating. After liquid deposition, the liquid medium can be removed in air, in an inert atmosphere, or by vacuum, at room temperature or with heating.

The photoactive layer can be deposited from any liquid medium in which it is dissolved or dispersed and from which it will form a film. In one embodiment, the liquid medium consists essentially of one or more organic solvents. In one embodiment, the liquid medium consists essentially of water or water and an organic solvent. In one embodiment the organic solvent is an aromatic solvent. In one embodiment, the organic solvent is selected from chloroform, dichloromethane, toluene, anisole, 2-butanone, 3-pentanone, butyl acetate, acetone, xylene, mesitylene, chlorobenzene, tetrahydrofuran, diethyl ether, trifluorotoluene, and mixtures thereof. The photoactive material can be present in the liquid medium in a concentration of 0.2 to 2 percent by weight. Other weight percentages of photoactive material may be used depending upon the liquid medium. The photoactive layer can be applied by any continuous or discontinuous liquid deposition technique. In one embodiment, the photoactive layer is applied by spin coating. In one embodiment, the photoactive layer is applied by ink jet printing. In one embodiment, the photoactive layer is applied by continuous nozzle printing. In one embodiment, the photoactive layer is applied by slot-die coating. After liquid deposition, the liquid medium can be removed in air, in an inert atmosphere, or by vacuum, at room temperature or with heating.

The electron transport layer can be deposited by any vapor deposition method. In one embodiment, it is deposited by thermal evaporation under vacuum.

The electron injection layer can be deposited by any vapor deposition method. In one embodiment, it is deposited by thermal evaporation under vacuum.

The cathode can be deposited by any vapor deposition method. In one embodiment, it is deposited by thermal evaporation under vacuum.

### EXAMPLES

The concepts described herein will be further described in the following examples, which do not limit the scope of the invention described in the claims.

### Synthesis Example 1

This example illustrates the synthesis of Compound L4 and Compound B4.

The synthesis was carried out in three steps as follows:

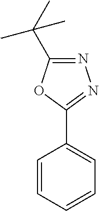

### Step 1: Synthesis of 2-tert-Butyl-5-phenyl-1,3,4-oxadiazole

In a fume hood, 5-phenyltetrazole (5.17 g, 35.4 mmol) was added to a 250 mL 2-neck round-bottom flask containing a magnetic stir bar, followed by the dropwise addition pivaloyl chloride (6.1 mL, 49.5 mmol) and then pyridine (50 mL). The reaction mixture was stirred and refluxed at 90° C. for 16 h. Nitrogen evolution was observed after 15 minutes. A precipitate was observed in the flask. The mixture was poured onto ice and the product was extracted with ethyl acetate, collected, dried over MgSO₄ and concentrated. The product was used without further purification (7.0 g, quantitative yield). ¹H NMR (500 MHz, CD₂Cl₂) δ 8.03-8.00 (m, 2H, ArH), 7.52-7.47 (m, 3H, ArH), 1.46 (s, 9H, C(CH₃)₃).

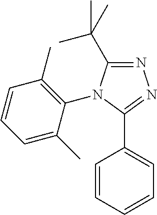 [SMILES: Cc1cccc(C)c1-n1c(-c2ccccc2)nnc1C(C)(C)C]

### Step 2: Synthesis of 3-tert-butyl-4-(2,6-dimethylphenyl)-5-phenyl-4H-1,2,4-triazole, Compound L4

Reference: Chiriac, C. I.; Tanasa, F.; Nechifor, M. Revue Roumaine de Chimie 2010, 55, 175-177

Inside a glovebox, a 300 mL Schlenk tube containing a stirbar was charged with 2,6-dimethylaniline (32.75 g, 270.3 mmol). The 2,6-dimethylaniline was stirred and treated with anhydrous aluminum chloride (8.5 g, 64 mmol) in small portions. The resulting solution was stirred under nitrogen and heated at 138-140° C. for 2.5 h to afford a red-purple solution. The mixture was kept under nitrogen and treated with 2-tert-butyl-5-phenyl-1,3,4-oxadiazole (20.0 g, 98.9 mmol) followed by anhydrous 1-methyl-2-pyrrolidinone (35 mL). The mixture was heated at reflux for a total of 89 h and then water was added to quench the mixture. The mixture was extracted several times with ethyl acetate, and the extracts were combined and dried over MgSO₄. The mixture was filtered and the filtrate was concentrated to afford brown solid. The oil was chromatographed on a Biotage® 340 g silica gel column. After drying under high vacuum at room temperature the desired product was obtained as a white solid (13.5 g, 55% yield). ¹H NMR (CD₂Cl₂) δ 7.37-7.31 (m, 4H, ArH), 7.28-7.24 (m, 2H, ArH), 7.20-7.17 (m, 2H, ArH), 2.01 (s, 6H, Ar(CH₃)₂), 1.29 (s, 9H, ArC(CH₃)₃).

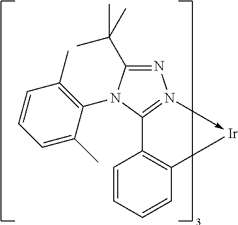

### Step 3: Synthesis of fac-tris{2-[4-(2,6-dimethylphenyl)]-5-tert-butyl-4H-1,2,4-triazol-3-yl-κN₂]phenyl-κC}iridium, Compound B4

A 10-mL stainless steel pressure vessel under nitrogen was charged with a mixture of the ligand 3-tert-butyl-4-(2,6-dimethylphenyl)-5-phenyl-4H-1,2,4-triazole (2.2 g, 7.20 mmol) and iridium tris-acetylacetonate (1.07 g, 2.18 mmol). The vessel was sealed tightly while under nitrogen. The vessel was then heated over a ˜1 h period to an internal temperature of 248° C. The mixture was heated at 248° C. for 68 h. The mixture was cooled to room temperature to leave a dark solid. It was triturated several times with ethyl acetate and transferred to a 500 mL flask. The mixture was concentrated to afford a dark glass. The glass was chromatographed on a Biotage® 100 g silica gel column. Fractions containing product were combined and concentrated to afford 1.00 g of a yellow glass. This was dissolved in boiling toluene. Then hexanes were added dropwise and the mixture was kept warm. The solution was allowed to cool to room temperature and stand overnight as a yellow solid formed. The yellow solid was filtered off, washed several times with hexanes, washed twice with hexane, and dried under high vacuum at room temperature to afford the desired product as a yellow solid (0.8 g, 33%). ¹H NMR (CD₂Cl₂) δ 7.44 (t, J=7.6 Hz, 3H, ArH), 7.32-7.24 (m, 8H, ArH), 6.65 (dd, J=1.0, 7.6 Hz, 3H, ArH), 6.60 (dt, J=1.3, 5.9 Hz, 3H, ArH), 6.46 (m, 3H, ArH), 5.97 (dd, J=0.8, 7.8 Hz, 3H, ArH), 2.17 (s, 9H, Ar(CH₃)₂), 1.93 (s, 9H, Ar(CH₃)₂), 1.23 (s, 27H, ArC(CH₃)₃). LC/MS (SQ with ESI) C₆₀H₆₆IrN₉ calcd: 1106.48 ([M+H]+); Found: 1106.29. LC purity: 99.83%.

### Synthesis Example 2

This example illustrates the synthesis of Compound L5 and Compound B5.

The synthesis was carried out in two steps as follows:

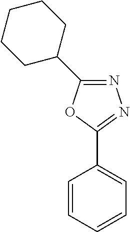 [SMILES: c1ccc(-c2nnc(C3CCCCC3)o2)cc1]

### Step 1: Synthesis of 2-cyclohexyl-5-phenyl-1,3,4-oxadiazole

Reference: Stabile, P.; Lamonica, A.; Ribecai, A.; Castoldi, D.; Guercio, G.; Curcuruto, O. Tetrahedron Lett. 2010, 51, 4801

Into a 1-L RBF, cyclohexanecarboxylic acid (6.93 g, 54.1 mmol) was added as a solid under a positive flow of N₂. After addition of the acid was completed, benzhydrazide (7.386 g, 54.25 mmol) and Hunig's base (27 mL, 150 mmol) and acetonitrile (600 mL) were added while stirring.

O-(benzotriazol-1-yl)-N,N,N′,N′-tetramethyluronium tetrafluoroborate (TBTU) was then added while stirring. The resulting mixture was stirred for 4.5 h. TLC analysis (1:1 hexanes:ethylacetate) showed full conversion of benzhydrazide. Hunig's base (17.4 mL) was then added, followed by tosyl chloride (30 g, 150 mL). The resulting reaction mixture was stirred overnight. The reaction mixture was concentrated under reduced pressure. The solution was washed with water, dried over anhydrous Na₂SO₄, filtered and concentrated under reduced pressure. The crude product was stirred in dichloromethane and pyridine (10 mL) and ethylene glycol (7 mL). The mixture was then washed with water (150 mL), dried over Mg₂SO₄ then filtered. TLC analysis indicated full conversion of the tosyl chloride. The product was purified by Biotage® chromatography to give the desired product as a white solid (8.2 g, 72%). ¹H NMR (CD₂Cl₂) δ 8.04 (m, 2H, ArH), 7.57-7.51 (m, 3H, ArH), 3.00 (tt, J=3.6, 11.3 Hz, 1H, cyclohexyl methine), 2.15 (m, 2H, CH(CH₂CH₂)₂CH₂), 1.88 (m, 2H, CH(CH₂CH₂)₂CH₂), 1.79-1.65 (m, 3H, CH(CH₂CH₂)₂CH₂), 1.51-1.32 (m, 3H, CH(CH₂CH₂)₂CH₂).

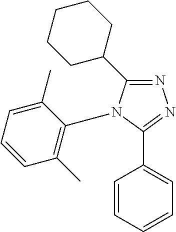 [SMILES: Cc1cccc(C)c1-n1c(-c2ccccc2)nnc1C1CCCCC1]

### Step 2: Synthesis of 3-cyclohexyl-4-(2,6-dimethylphenyl)-5-phenyl-4H-1,2,4-triazole, Compound L5

Reference: Chiriac, C. I.; Tanasa, F.; Nechifor, M. Revue Roumaine de Chimie 2010, 55, 175-177

Inside a glovebox, a 300 mL Schlenk tube containing a stirbar was charged with 2,6-dimethylaniline (3.31 g, 27.3 mmol). The 2,6-dimethylaniline was stirred and treated with anhydrous aluminum chloride (0.907 g, 6.80 mmol) in small portions. The resulting solution was stirred under nitrogen and heated at 138-140° C. for 1 h to afford a red-purple solution. The mixture was kept under nitrogen and treated with 2-cyclohexyl-5-phenyl-1,3,4-oxadiazole (2.28 g, 10.0 mmol) followed by anhydrous 1-methyl-2-pyrrolidinone (3 mL). The mixture was heated at reflux for a total of 68 h and then water was added to quench the mixture.

The mixture was extracted several times with ethyl acetate, and the extracts were combined and dried over MgSO₄. The mixture was filtered and the filtrate was concentrated to afford brown solid. The oil was chromatographed on a Biotage® 340 g silica gel column. After drying under high vacuum at room temperature the desired product was obtained as a white solid. ¹H NMR (CD₂Cl₂) δ 8.04 (m, 2H, ArH), 7.39-7.32 (m, 4H, ArH), 7.25-7.29 (m, 2H, ArH), 7.24-7.22 (m, 2H, ArH), 2.22 (m, 1H, cyclohexyl methine), 1.95 (s, 6H, Ar(CH₃)₂), 1.83-1.73 (m, 2H, cyclohexyl methylenes), 1.66 (m, 1H, cyclohexylmethylene), 1.32 (m, 1H, cyclohexyl methylene), 1.17 (m, 1H, cyclohexyl methylene).

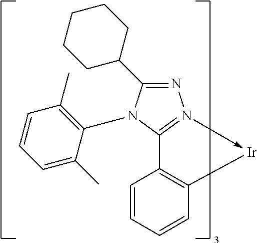

### Step 3: Synthesis of fac-tris{2-[4-(2,6-diisopropylphenyl)]-5-(o-tolyl)-4H-1,2,4-triazol-3-yl-κN²]phenyl-κC}iridium 3-cyclohexyl-4-(2,6-dimethylphenyl)-5-phenyl-4H-1,2,4-triazole, Compound B5

A 20 ml vial was charged with 3-cyclohexyl-4-(2,6-dimethylphenyl)-5-phenyl-4H-1,2,4-triazole (1.004 g, 3.003 mmol) and iridium tris(acetylacetonate) (0.447 g, 9.13 mmol). The mixture was mixed well and transferred into a 10-mL stainless steel tube. The tube was heated at 250° C. for 3 days. Purification of the product was performed with Biotage® chromatography to give a yellow powder (0.20 g, 19%). ¹H NMR (CD₂Cl₂) δ 7.39 (t, J=7.6 Hz, 3H, ArH), 7.27 (dd, J=7.7, 10.9 Hz, 6H, ArH), 6.68 (m, 3H, ArH), 6.59 (dt, J=1.3, 7.4 Hz, 3H, ArH), 6.45 (dt, J=1.2, 7.4 Hz, 3H, ArH), 6.14 (dd, J=1.1, 7.7 Hz, 3H, ArH), 2.19 (tt, J=3.6, 11.6 Hz, 3H, cyclohexyl methine), 2.12 (s, 9H, Ar(CH₃)₂), 1.89 (m, 2H, cyclohexyl methylenes), 1.86 (s, 9H, Ar(CH₃)₂), 1.77-1.70 (m, 6H, cyclohexyl methylenes), 1.69-1.56 (m, 10H, cyclohexyl methylenes), 1.51 (dq, J=3.5, 12.2 Hz, 3H, cyclohexyl methylenes), 1.25-1.02 (m, 9H, cyclohexylmethylenes). LC/MS (SQ with ESI) C₆₆H₇₂IrN₉ calcd: 1184.57 ([M+H]+); Found: 1184.38. LC purity: 99.78%

### Synthesis of Comparative Compounds A and B

Comparative Compound A was synthesized in four convergent steps as follows:

The synthesis was carried out in two steps as follows:

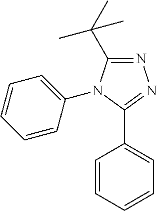 [SMILES: CC(C)(C)c1nnc(-c2ccccc2)n1-c1ccccc1]

### Step 1: Synthesis of 3-tert-Butyl-4-phenyl-5-phenyl-4H-1,2,4-triazole

Reference: Chiriac, C. I.; Tanasa, F.; Nechifor, M. Revue Roumaine de Chimie 2010, 55, 175-177

Inside the glovebox, aniline (2.55 g, 27.4 mmol) was added to a 25-mL Schlenk tube containing a stir bar. The mixture was stirred and treated with anhydrous aluminum(III) chloride (0.91 g, 6.8 mmol) in small portions with stirring to give a light tan solution. The mixture was stirred for 1.5 h at 140° C. to give a light red solution. The mixture was treated with 2-tert-butyl-5-phenyl-1,3,4-oxadiazole (see Example 3, 1.98 g, 9.79 mmol) followed by anhydrous NMP (1.5 mL) and heated at 210° C. for 15.5 h. The reaction mixture was a solid at this point, no stirring was possible. The tube was removed from the glovebox and the reaction mixture was analyzed by GC/MS, which showed that only the desired product was present. The reaction mixture was stirred in a biphasic mixture of 1N aqueous HCl and 300 mL of ethyl acetate. The organic layer was separated, dried over MgSO₄, filtered and concentrated. TLC analysis (1:3 hexanes:ethyl acetate) was performed. Biotage® chromatography was run on a SNAP 100 g column to give a colorless powder (0.90 g, 33%). ¹H NMR (500 MHz, CD₂Cl₂) δ 7.49 (m, 3H, ArH), 7.32-7.25 (m, 5H, ArH), 7.23-7.19 (m, 2H, ArH), 1.27 (s, 9H, C(CH₃)₃).

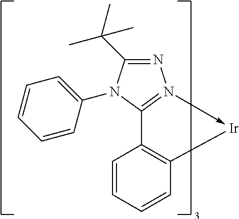

### Step 2: Synthesis of fac-tris[2-(5-tert-butyl-4-phenyl-4H-1,2,4-triazol-3-yl-κN²)phenyl-κC¹]iridium, Comparative Compound A

3-tert-Butyl-4-phenyl-5-phenyl-4H-1,2,4-triazole (0.85 g, 3.1 mmol) and iridium acetylacetonate (0.453 g, 0.93 mmol) were combined and mixed well. The stainless steel, 6-mL tube was brought into the glovebox, charged with the solid mixture and sealed under N₂. The reactor was set at 241° C. internal temperature for 72 h with automatic heat shut off. After 72 h, the reactor was cooled to room temperature. The crude materials were washed out of the reactor tube with dichloromethane. The product was purified by Biotage® chromatography with a SNAP 100 g column, followed by recrystallization. In the glovebox, the beige solid was dissolved in minimal amounts of dichloromethane, then precipitated using toluene, and then redissolved with a few drops of dichloromethane. The vial was placed in the fridge. The crystals were collected, washed with toluene, and dried under reduced pressure (300 mTorr) to give a yellow powder (0.11 g, 12%). ¹H NMR (500 MHz, CD₂Cl₂) δ 7.64-7.55 (m, 9H, ArH), 7.46-7.44 (m, 3H, ArH), 7.42-7.40 (m, 3H, ArH), 6.82 (m, 3H, ArH), 6.63 (dt, J=1.3, 7.4 Hz, 3H, ArH), 6.43 (m, 3H, ArH), 5.91 (dd, J=1.1, 7.8 Hz, ArH), 1.24 (s, 27H, C(CH₃)₃). LC-MS (LTQ/Orbitrap with EI) C₅₄H₅₄IrN₉ calcd: 1022.36 ([M+H]+); Found: 1022.47.

Comparative Compound B was synthesized in four steps.

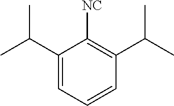

### Step 1: Synthesis of 2-isocyano-1,3-diisopropylbenzene Reference: Weber, W. P.; Gokel, G. W.; Ugi, I. K. Angew. Chem., Int. Ed. 1972, 11, 530

A 2-neck, 500-mL round-bottom flask equipped with a stir bar, thermometer, a nitrogen inlet bubbler and a cooling condenser was charged with 2,6-diisopropyaniline (25 g, 141 mmol), benzyltriethylammonium chloride (0.38 g, 1.7 mmol), chloroform (11.3 mL, 141 mmol), and dichloromethane (35 mL). An aqueous 50% sodium hydroxide solution (45 mL) was then added. The solution was rinsed in with water (5 mL). The mixture was stirred at 25° C. for approximately 4 h, then stirred at 43° C. for 24 h. The reaction mixture was then diluted with deionized water (500 mL) and extracted with dichloromethane (2×250 mL). The organic layers were combined and washed with deionized water, followed by brine, separated and dried over K₂CO₃, filtered and concentrated under reduced pressure to give a brown oil (26.9 g). The crude oil was purified by flash column chromatography (4:1 hexanes:dichloromethane) to give a dark brown oil (20 g, 75%). ¹H NMR (500 MHz, CD₂Cl₂) δ 7.35 (m, 1H, p-ArH), 7.19 (m, 2H, m-ArH), 3.38 (m, 2H, ArCH(CH₃)₂), 1.28 (d, 12H, ArCH(CH₃)₂)).

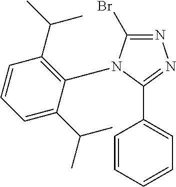 [SMILES: CC(C)c1cccc(C(C)C)c1-n1c(Br)nnc1-c1ccccc1]

### Step 2: Synthesis of 3-bromo-4-(2,6-diisopropylphenyl)-5-phenyl-4H-1,2,4-triazole

Reference: This is a classic Huisgen rearrangement reaction

An oven-dried 100-mL round-bottom flask equipped with a stir bar, rubber septum and a nitrogen bubbler was charged with 2-isocyano-1,3-diisopropylbenzene (5 g, 27 mmol) and dichloromethane (60 mL). The flask was placed in a water bath at 25° C. and bromine (1.4 mL, 27 mmol) was added dropwise over a period of 2-3 minutes via a plastic syringe. The flask was removed from the water bath, covered with aluminum foil and stirred at 25° C. for 19 h. Another 100-mL round-bottom flask was charged with 5-phenyl-1H-tetrazole (3.95 g, 27 mmol) in dichloromethane (45 mL). Triethylamine (7.5 mL, 54 mmol) was added via a syringe to this suspension, which became homogeneous. This tetrazole solution was transferred to the other round-bottom flask via a cannula over a period of 2 min. The mixture was stirred at 25° C. for 23 h. The mixture was concentrated under reduced pressure to give a brown sludge. The sludge was dissolved in ethyl acetate (300 mL) and washed with water (2×250 mL) then brine, separated, dried over MgSO₄. The resulting imidoyl bromide was purified on a Biotage® column chromatography to give 2.2 g of brown oil (20%). This oil was then dissolved in anhydrous toluene and the mixture was refluxed under nitrogen for 1.5 h. The reaction mixture was concentrated under reduced pressure and the crude product was dissolved in a minimal amount of dichloromethane and then passed through a plug of 50 g silica gel by eluting with 1% ethyl acetate in dichloromethane, then 2%, and 5% mixtures to give 1.75 g of an off-white powder (16% overall yield). ¹H NMR (500 MHz, CD₂Cl₂) δ 7.60 (m, 1H, ArH), 7.48 (m, 2H, ArH), 7.37 (m, 3H, ArH), 7.28 (m, 2H, ArH), 2.08 (m, 2H, ArCH(CH₃)₂), 1.20 (d, 6H, ArCH(CH₃)₂), 0.89 (d, 6H, ArCH(CH₃)₂).

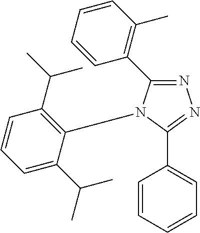 [SMILES: Cc1ccccc1-c1nnc(-c2ccccc2)n1-c1c(C(C)C)cccc1C(C)C]

### Step 3: Synthesis of 4-(2,6-diisopropylphenyl)-3-phenyl-5-(o-tolyl)-4H-1,2,4-triazole

A 2-neck, 100-mL round-bottom flask equipped with a stir bar, condenser, nitrogen bubbler, and a nitrogen sparge tube was charged with K₃PO₄ (1.8 g, 7.8 mmol), o-tolyl boronic acid (0.70 g, 5.2 mmol), toluene (40 mL) and 3-bromo-4-(2,6-diisopropylphenyl)-5-phenyl-4H-1,2,4-triazole (1.0 g, 2.6 mmol). The mixture was sparged with nitrogen for 40 min. In a drybox, a round-bottom flask equipped with a stir bar was charged with tris(benzylideneacetone)dipalladium (0.12 g, 0.13 mmol), 2-dicyclohexylphosphino-2′,6′-dimethoxybiphenyl (0.21 g, 0.52 mmol) and toluene (15 mL). The dark purple solution was stirred for 20 min. This solution was transfer to the reaction mixture via a cannula and the reaction mixture was refluxed under a nitrogen atmosphere for 15.5 h. The reaction mixture was then diluted with a 1:1 ethylacetate:dichloromethane mixture and filtered through a column. The crude product was concentrated under reduced pressure and purified by Biotage® column chromatography to give 0.7 g (75%) of a colorless powder. ¹H NMR (500 MHz, CD₂Cl₂) δ 7.60 (m, 1H, ArH), 7.48 (m, 2H, ArH), 7.37 (m, 3H, ArH), 7.28 (m, 2H, ArH), 2.08 (m, 2H, ArCH(CH₃)₂), 1.20 (d, 6H, ArCH(CH₃)₂), 0.89 (d, 6H, ArCH(CH₃)₂).

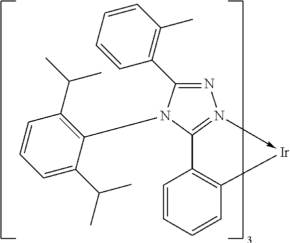

### Step 4: Reaction of Ir(acac)₃ with 4-(2,6-diisopropylphenyl)-3-phenyl-5-(o-tolyl)-4H-1,2,4-triazole to synthesize fac-Tris{N²-κ-C²-(3-(4-(2,6-diisopropylphenyl)-5-(o-tolyl)-4H-1,2,4-triazolyl)phenyl)iridium, Comparative Compound B

A 10-mL stainless steel pressure tube was charged with a premixed powder containing 4-(2,6-diisopropylphenyl)-3-phenyl-5-(o-tolyl)-4H-1,2,4-triazole (0.69 g, 1.75 mmol) and tris(acetylacetonate)iridium (0.26, 0.53 mmol). The tube was pressured with sparged nitrogen to 0 psig and heated to 250° C. for 3 d during which the pressure reached 170 psig. After cooling to room temperature the crude material was removed from the tube with a spatula and the remaining materials are rinsed with dichloromethane. The materials were concentrated under reduced pressure to give 0.8 g of crude product. Purification was performed by Biotage® column chromatography to give 0.360 g of a yellow powder. Further purification was performed on the Biotage to give 0.125 g of a colorless solid (17%) with 99.4% purity by UPLC. ¹H NMR (500 MHz, CD₂Cl₂) δ 7.51 (m, 3H, ArH), 7.26 (m, 6H, ArH), 7.23 (m, 3H, ArH), 7.18 (m, 3H, ArH), 6.89 (m, 3H, ArH), 6.84 (m, 6H, ArH), 6.70 (m, 3H, ArH), 6.5 (m, 3H, ArH), 6.19 (m, 3H, ArH), 2.81 (m, 3H, ArCH(CH₃)₂, 2.31 (s, 12H, ArCH₃, 2.29 (m, 3H, ArCH(CH₃)₂), 0.95 (d, 9H, ArCH(CH₃)₂), 0.81 (d, 9H, ArCH(CH₃)₂), 0.77 (d, 9H, ArCH(CH₃)₂), 0.73 (d, 9H, ArCH(CH₃)₂).

### Synthesis of Comparative Compound C

The synthesis is carried out in three steps:

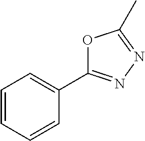

### Step 1. Synthesis of 2-methyl-5-phenyl-1,3,4-oxadiazole

Reference: This is a classic Huisgen rearrangement reaction

In a fume hood, 5-phenyltetrazole (3.64 g, 24.5 mmol) was added to a 250-mL RBF containing a magnetic stir bar, followed by VERY CAREFUL dropwise addition acetic anhydride (14 mL, 150 mmol). The reaction mixture was stirred at 120° C. for 15 h. It was then diluted with water and heated at 50° C. for 2 h. The product was extracted with ethyl acetate. The organic layer was separated from the aqueous layer and was dried over Na₂SO₄, filtered and concentrated under reduced pressure. Purification was performed with Biotage® chromatography to yield a colorless oil, from which crystallization overnight gave colorless crystals. The crystals were isolated and placed under reduced pressure to give the desired product (3.38 g, 85%). ¹H NMR (500 MHz, CD₂Cl₂) δ 8.04 (m, 2H, ArH), 7.58-7.51 (m, 3H, ArH), 2.60 (s, 3H, triazole-CH₃).

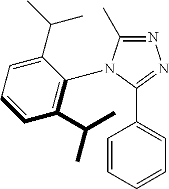

### Step 2. Synthesis of 4-(2,6-diisopropylphenyl)-3-methyl-5-phenyl-4H-1,2,4-triazole

Reference: Chen, X.; Liu, R.; Xu, Y.; Zou, G. Tetrahedron 2012, 68, 4813

2-Methyl-5-phenyl-1,3,4-oxadiazole (3.338 g, 20.84 mmol), 2,6-diisopropylaniline (7.038 g, 39.70 mmol) and pyridinium triflate (20.329 g, 105.60 mmol) were added to a flame-dried, 3-neck, 250-mL round-bottom flask containing a magnetic stirbar and equipped with a reflux condenser. The reactor was evacuated for 5 minutes. The reaction mixture was stirred at 110° C. for 41 h. Water (150 mL) was then added followed by ethyl acetate (150 mL). The crude product was extracted in a separatory funnel. The organic layer was collected, dried over MgSO₄ and filtered. Ethyl acetate was removed under reduced pressure. Purification was performed with Biotage® chromatography. The desired product was isolated to give a white solid (1.0 g, 17%). ¹H NMR (500 MHz, CD₂Cl₂) δ 7.57 (t, 1H, ArH), 7.48 (m, 2H, ArH), 7.36 (d, J=7.8 Hz, 2H, ArH), 7.32 (m, 1H, ArH), 7.26 (m, 2H, ArH), 2.38 (sept, J=6.8 Hz, 2H, CH(CH₃)₂), 2.23 (s, 3H, triazole-CH₃), 1.15 (d, J=6.8 Hz, 6H, CH(CH₃)₂), 0.88 (d, J=6.8 Hz, 6H, CH(CH₃)₂).

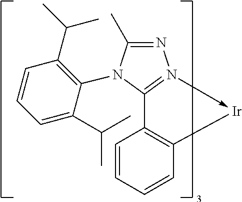

### Step 3. Synthesis of Tris{4-(2,6-diisopropylphenyl)-3-methyl-5-phenyl-4H-1,2,4-triazole-κN²]phenyl-κC}iridium, Comparative Compound C

4-(2,6-diisopropylphenyl)-3-methyl-5-phenyl-4H-1,2,4-triazole (0.943 g, 2.95 mmol) and iridium(III) acetylacetonate (0.438 g, 0.895 mmol) were combined and mixed in a 20-mL vial. The mixture was added to a 10-mL stainless steel tube and heated at 250° C. for 3 days. The product was purified by Biotage® chromatography to give a yellow powder (287 mg, 28%). The product was recrystallized twice from dichloromethane and hexanes to give a yellow solid (0.15 g, 15%). ¹H NMR (500 MHz, CD₂Cl₂) δ 7.60 (t, J=7.8 Hz, 3H, ArH), 7.42 (d, J=7.8 Hz, 3H, ArH), 7.39 (d, J=7.8 Hz, 3H, ArH), 6.81 (d, J=7.4 Hz, 3H, ArH), 6.66 (dt, J=1.1, 7.4 Hz, 3H, ArH), 6.48 (m, 3H, ArH), 6.24 (d, J=7.2 Hz, 3H, ArH), 2.77 (sept, J=6.8 Hz, 3H, CH(CH₃)₂), 2.29 (sept, J=6.8 Hz, 3H, CH(CH₃)₂), 2.16 (s, 9H, triazole-CH₃), 1.24 (d, J=6.8 Hz, 9H, CH(CH₃)₂, 0.99 (d, J=6.8 Hz, 9H, CH(CH₃)₂), 0.97 (d, J=6.8 Hz, 9H, CH(CH₃)₂), 0.93 (d, J=6.8 Hz, 9H, CH(CH₃)₂). LC/MS (SQ with ESI) C₆₃H₇₂IrN₉ calcd: 1148.53 ([M+H]+); Found: 1148.29. LC purity: 99.86%.

### Device Examples

These examples demonstrate the fabrication and performance of OLED devices.

### (1) Materials

HIJ-1 is an electrically conductive polymer doped with a polymeric fluorinated sulfonic acid. Such materials have been described in, for example, published U.S. patent applications US 2004/0102577, US 2004/0127637, US 2005/0205860, and published PCT application WO 2009/018009.
HT-1 is a triarylamine-containing polymer. Such materials have been described in, for example, published PCT application WO 2009/067419.
Host-1 is the carbazole-furan derivative shown below

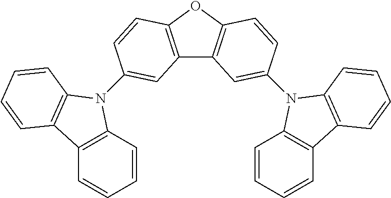 [SMILES: c1ccc2c(c1)c1ccccc1n2-c1ccc2oc3ccc(-n4c5ccccc5c5ccccc54)cc3c2c1]

Host-2 is the carbazole-thiophene derivative shown below

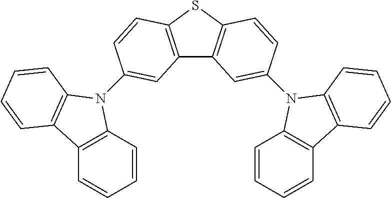 [SMILES: c1ccc2c(c1)c1ccccc1n2-c1ccc2sc3ccc(-n4c5ccccc5c5ccccc54)cc3c2c1]

ET-1 is a metal quinolate complex.
Comparative Compounds A1 and A2 are discussed above.
   The devices had the following structure on a glass substrate:
   anode=Indium Tin Oxide (ITO), 50 nm
   hole injection layer=HIJ-1 (50 nm)
   hole transport layer=HT-1 (20 nm)
   photoactive layer, discussed below=100:14 Host:dopant ratio (43 nm);
   anti-quenching layer=Host-1 or Host-2 (10 nm)
   electron transport layer=ET-1 (10 nm)
   electron injection layer/cathode=CsF/Al (1/100 nm)

### (2) Device Fabrication

OLED devices were fabricated by a combination of solution processing and thermal evaporation techniques. Patterned indium tin oxide (ITO) coated glass substrates from Thin Film Devices, Inc were used. These ITO substrates are based on Corning 1737 glass coated with ITO having a sheet resistance of 30 ohms/square and 80% light transmission. The patterned ITO substrates were cleaned ultrasonically in aqueous detergent solution and rinsed with distilled water. The patterned ITO was subsequently cleaned ultrasonically in acetone, rinsed with isopropanol, and dried in a stream of nitrogen.

Immediately before device fabrication the cleaned, patterned ITO substrates were treated with UV ozone for 10 minutes. Immediately after cooling, an aqueous dispersion of HIJ-1 was spin-coated over the ITO surface and heated to remove solvent. After cooling, the substrates were then spin-coated with a hole transport solution, and then heated to remove solvent. The substrates were masked and placed in a vacuum chamber. The photoactive layer, the electron transport layer and the anti-quenching layer were deposited by thermal evaporation, followed by a layer of CsF. Masks were then changed in vacuo and a layer of Al was deposited by thermal evaporation. The chamber was vented, and the devices were encapsulated using a glass lid, dessicant, and UV curable epoxy.

### (3) Device Characterization

The OLED samples were characterized by measuring their (1) current-voltage (I-V) curves, (2) electroluminescence radiance versus voltage, and (3) electroluminescence spectra versus voltage. All three measurements were performed at the same time and controlled by a computer. The current efficiency of the device at a certain voltage is determined by dividing the electroluminescence radiance of the LED by the current density needed to run the device. The unit is a cd/A. The color coordinates were determined using either a Minolta CS-100 meter or a Photoresearch PR-705 meter.

### Examples 1 and 2, and Comparative Example A

This example illustrates the use of Compound B4, B5, and Comparative Compound A as the light-emitting material in a device. The results are given in Table 1 below.

TABLE 1
Device results

| | | | | | | T70 @ |
|---|---|---|---|---|---|---|
| | | | EL | | EQE | 1000 |
| | | | peak | | @1000 | nits |
| Example | Dopant | Host | (nm) | CIE (x, y) | nits (%) | (hours) |
| Com- | Com- | Host-2 | 473 | (0.189, 0.386) | 23.90% | 275 |
| parative A | pound | | | | | |
| | A | | | | | |
| 1 | B4 | Host-2 | 468 | (0.177, 0.352) | 20.40% | 185 |
| 2 | B5 | Host-2 | 467 | (0.17, 0.31) | 14.00% | 89 |

All data @ 1000 nits.
E.Q.E. is the external quantum efficiency;
CIE(x, y) are the x and y color coordinates according to the C.I.E. chromaticity scale (Commission Internationale de L'Eclairage, 1931);
T70 is a measure of lifetime and is the time to reach 70% of initial luminance.

It can be seen from the results that the peak wavelength is blue-shifted and the color is deeper blue in the devices with the compounds having Formula II, Compound B4 and B5, as the light-emitting material. With further optimization of the deeper blue device structure, it is believed that both the efficiency and lifetime can be improved.

### Example 3 and Comparative Example B

This example illustrates the use of Compound B4, and Comparative Compound B as the light-emitting materials in a device. The results are given in Table 2 below.

TABLE 2
Device results

| | | | | | | T70 @ |
|---|---|---|---|---|---|---|
| | | | EL | | EQE | 1000 |
| | | | peak | | @1000 | nits |
| Example | Dopant | Host | (nm) | CIE (x, y) | nits (%) | (hours) |
| Com- | Com- | Host-1 | 476 | (0.187, 0.386) | 22.3% | 700 |
| parative B | pound | | | | | |
| | B | | | | | |
| 3 | B4 | Host-1 | 464 | (0.165, 0.285) | 20.00 | 350 |

All data @ 1000 nits.
E.Q.E. is the external quantum efficiency;
CIE(x, y) are the x and y color coordinates according to the C.I.E. chromaticity scale (Commission Internationale de L'Eclairage, 1931);
T70 is a measure of lifetime and is the time to reach 70% of initial luminance.

It can be seen from the results that the peak wavelength is blue-shifted and the color is deeper blue in the device with the compound having Formula II, Compound B4, as the light-emitting material. With further optimization of the deeper blue device structure, it is believed that both the efficiency and lifetime can be improved.

### Examples 3 and Comparative Example C

This example illustrates the use of Compound B4 and Comparative Compounds C as the light-emitting materials in a device. The results are given in Table 3 below.

TABLE 3
Device results

| | | | | | | T70 @ |
|---|---|---|---|---|---|---|
| | | | EL | | EQE | 1000 |
| | | | peak | | @1000 | nits |
| Example | Dopant | Host | (nm) | CIE (x, y) | nits (%) | (hours) |
| Com- | Com- | Host-1 | 464 | (0.163, 0.271) | 21% | 25 |
| parative C | pound | | | | | |
| | C | | | | | |
| 3 | B4 | Host-1 | 464 | (0.165, 0.285) | 20% | 350 |

All data @ 1000 nits.
E.Q.E. is the external quantum efficiency;
CIE(x, y) are the x and y color coordinates according to the C.I.E. chromaticity scale (Commission Internationale de L'Eclairage, 1931);
T70 is a measure of lifetime and is the time to reach 70% of initial luminance.

It can be seen from Table 3, Compound B4 and Comparative compound C have comparable color and efficiency. However, T70 lifetime of Compound B4 is much longer than Comparative Compound C.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges include each and every value within that range.

What is claimed is:

1. A compound having Formula II 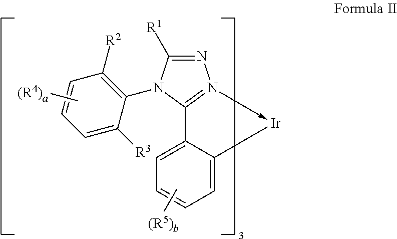
wherein:
R¹ is selected from the group consisting of branched alkyl, cyclic alkyl, silyl, and deuterated analogs thereof;
R²-R³ are the same or different and are selected from the group consisting of alkyl, silyl, and deuterated analogs thereof;
R⁴-R⁵ are the same or different at each occurrence and are selected from the group consisting of D, alkyl, silyl, aryl, deuterated alkyl, deuterated silyl, and deuterated aryl;
a is an integer from 0-3; and
b is an integer from 0-4.

2. The compound of claim 1, wherein the compound is at least 10% deuterated.

3. The compound of claim 1, wherein R¹ is a branched alkyl or deuterated branched alkyl having 3-12 carbons.

4. The compound of claim 1, wherein R¹ is a branched alkyl or deuterated branched alkyl having 4-6 carbons.

5. The compound of claim 1, wherein R² and R³ are the same groups.

6. The compound of claim 1, wherein R² and R³ are alkyl or deuterated alkyl groups having 1-6 carbons.

7. The compound of claim 1, wherein a>0 and R⁴ is an alkyl or deuterated alkyl having 1-6 carbons.

8. The compound of claim 1, wherein a=0.

9. The compound of claim 1, wherein b>0 and R⁵ is an alkyl or deuterated alkyl having 1-6 carbons.

10. The compound of claim 1, wherein b=0.

11. The compound of claim 1 selected from B1 through B11.

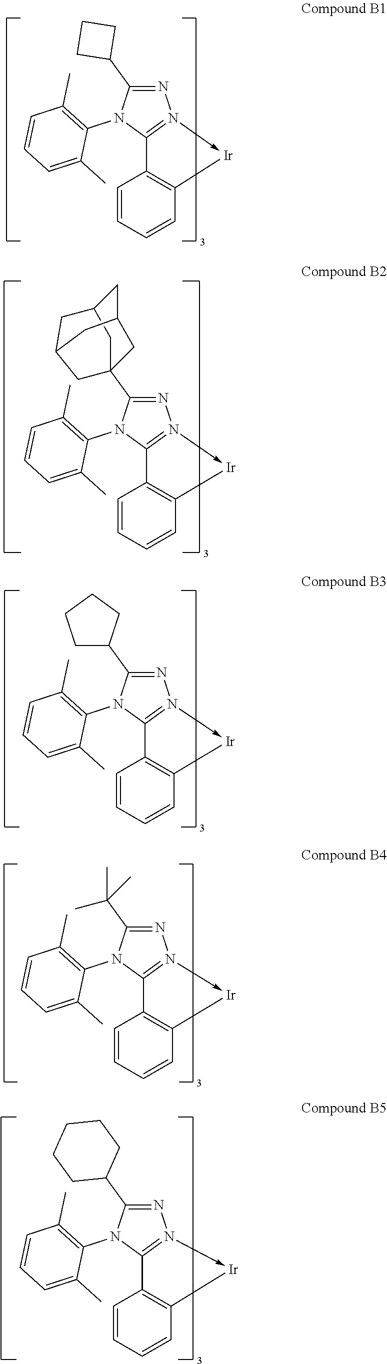

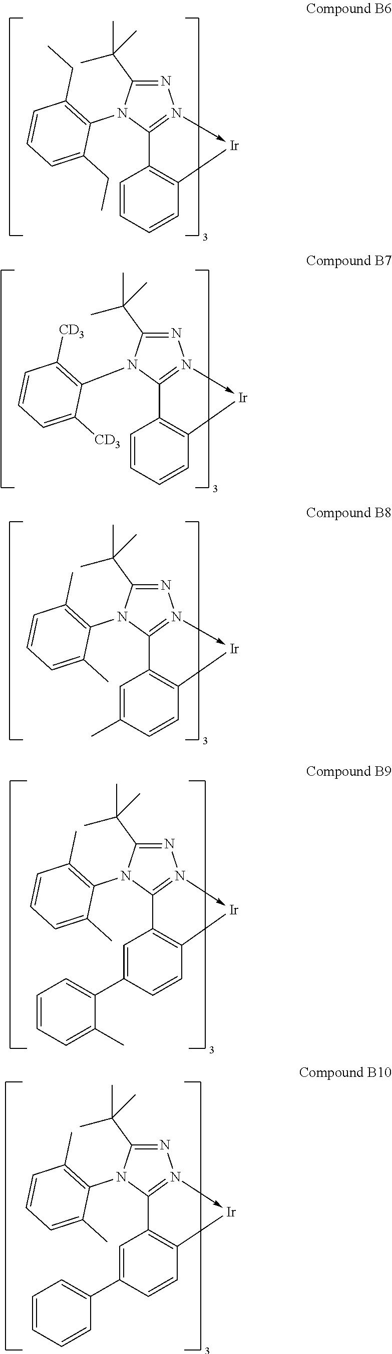

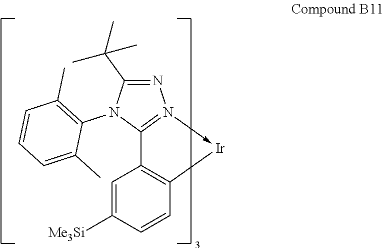

12. An organic electronic device comprising a first electrical contact, a second electrical contact and a photoactive layer therebetween, the photoactive layer comprising a compound having Formula II 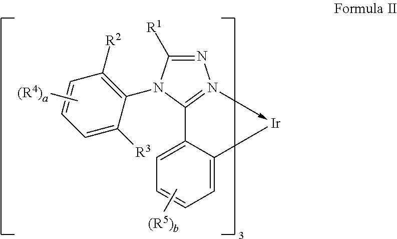
wherein:
R¹ is selected from the group consisting of branched alkyl, cyclic alkyl, silyl, and deuterated analogs thereof;
R²-R³ are the same or different and are selected from the group consisting of alkyl, silyl, and deuterated analogs thereof;
R⁴-R⁵ are the same or different at each occurrence and are selected from the group consisting of D, alkyl, silyl, aryl, deuterated alkyl, deuterated silyl, and deuterated aryl;
a is an integer from 0-3; and
b is an integer from 0-4.

13. The device of claim 12, wherein the photoactive layer further comprises a host material.

14. The device of claim 12, wherein the photoactive layer consists essentially of the compound of Formula II and a host material.

15. A compound having Formula I 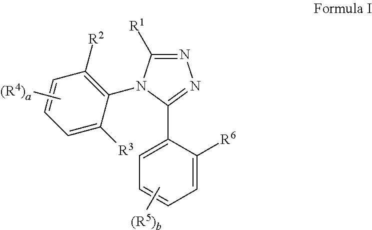
wherein:
R¹ is selected from the group consisting of branched alkyl, cyclic alkyl, silyl, and deuterated analogs thereof;
R²-R³ are the same or different and are selected from the group consisting of alkyl, silyl, and deuterated analogs thereof;
R⁴-R⁵ are the same or different at each occurrence and are selected from the group consisting of D, alkyl, silyl, aryl, deuterated alkyl, deuterated silyl, and deuterated aryl;
R⁶ is H or D;
a is an integer from 0-3; and
b is an integer from 0-4.

16. The compound of claim 15, wherein R¹ is a branched alkyl or deuterated branched alkyl having 3-12 carbons.

17. The compound of claim 15, wherein R¹ is a branched alkyl or deuterated branched alkyl having 4-6 carbons.

18. The compound of claim 15, wherein R² and R³ are the same groups.

19. The compound of claim 15, wherein a=0.

20. The compound of claim 15, wherein b=0.
